(19) United States
(12) Patent Application Publication
(10) Pub. No.: US 2010/0133091 A1
(43) Pub. Date: Jun. 3, 2010

(54) THIN FILM PRODUCING METHOD AND HEXAGONAL PIEZOELECTRIC THIN FILM PRODUCED THEREBY

(75) Inventors: Hidetoshi Nishio, Osaka (JP); Yoshikazu Mori, Nara (JP); Yoshitaka Tsurukame, Shiga (JP); Takayuki Kawamoto, Nara (JP); Yoshiaki Watanabe, Kyoto (JP); Takahiko Yanagitani, Kyoto (JP)

Correspondence Address: OSHA LIANG L.L.P., TWO HOUSTON CENTER, 909 FANNIN, SUITE 3500, HOUSTON, TX, 77010, US

(73) Assignees: OMRON CORPORATION, Kyoto-shi, Kyoto (JP); DOSHISYA UNIVERSITY, Kyoto-shi, Kyoto (JP)

(21) Appl. No.: 12/516,473

(22) PCT Filed: Nov. 22, 2007
(86) PCT No.: PCT/JP2007/072646

§ 371 Date: Feb. 1, 2010

(30) Foreign Application Priority Data
Nov. 27, 2006 (JP) 2006-318720

(51) Int. Cl. C23C 14/34; C23C 14/08

(52) U.S. Cl. 204/192.18; 204/192.12

(57) ABSTRACT

A magnetron circuit of a rectangular type is disposed on a lower surface of a rectangular target. A half of the target is covered with a shield plate, so that sputtering particles sputtered from an erosion region (a region with a maximized magnetic flux density) therebelow is blocked so as not to fly toward a substrate. The substrate is disposed at a level so as to be located in a plasma region of a vacuum chamber, and sputtering particles (ZnO) sputtered from a region exposed from the shield plate in the erosion region is caused to be incident on a surface of the substrate. When a gas pressure is lowered, a mean free path of each of the sputtering particles is lengthened to cause a large amount of high-energy sputtering particles to be incident. As a result, a hexagonal crystal particle having a plane that is a crystal plane hardly damaged by incidence of the high-energy sputtering particles is preferentially grown to form a c-axis in-plane oriented film.

### TECHNICAL FIELD

The present invention relates to a thin film producing method and a hexagonal piezoelectric thin film produced by the thin film producing method, specifically to a method for producing a poly-crystalline thin film or a single-crystal thin film which is oriented in a plane direction, a hexagonal piezoelectric thin film such as a zinc-oxide thin film obtained by the method, a piezoelectric element, a transducer, and a SAW device.

### BACKGROUND ART

Magnetron sputtering is a type of sputtering method which is widely used in the industrial field. In the magnetron sputtering apparatus, a substrate and a target are disposed to face each other in a chamber, and an Ar gas is caused to flow in the chamber so that the chamber is maintained at a pressure of several pascals to several tens of pascals. A magnet is disposed behind the target such that a magnetic field is generated at a target position. When a negative high voltage of several kilovolts is applied to the target to generate a discharge in the Ar gas atmosphere, the Ar gas is ionized to generate a plasma region between the target and the substrate. The positive ion (Ar⁺) collides with the target to sputter an atom or a molecule of the target (sputtering phenomenon). The sputtering particle flying out of the target is deposited on a surface of the substrate to form a thin film including the constituent atoms of the target on the surface of the substrate. In the magnetron sputtering of this case, because the magnetic field is concentrated in the target position, plasma density is increased near the surface of the target and the number of the sputtering particles flying out of the target is increased to enhance a thin film deposition rate.

Conventionally, there has been an attempt to deposit a ZnO thin film with the magnetron sputtering apparatus described above. For example, Patent Document 1 (Japanese Unexamined Patent Publication No. 11-284242) reports such a case. Patent Document 1 discloses a piezoelectric thin film including two ZnO thin films. According to paragraph 0041 of Patent Document 1, a conductive ZnO thin film is deposited in an Ar atmosphere by magnetron RF sputtering under deposition conditions of an RF power of 500 watts and a process gas pressure of 0.6 Pa without heating a substrate. Patent Document 1 also describes deposition of an insulative ZnO thin film by magnetron RF sputtering in an atmosphere of Ar+O₂.

Patent Document 2 (Japanese Patent No. 3561745) and Patent Document 3 (Japanese Unexamined Patent Publication No. 2006-83010) disclose techniques for obtaining a c-axis in-plane oriented ZnO thin film. In the former, crystal orientation is controlled by giving a temperature gradient to the substrate. In the latter, a thin film is obtained using an inclined substrate so that a c-axis in-plane oriented ZnO thin film is obtained in a large area. Principles of Patent Documents 2 and 3 are intrinsically different from the principle of the present invention.

Patent Document 1: Japanese Unexamined Patent Publication No. 11-284242

Patent Document 2: Japanese Patent No. 3561745

Patent Document 3: Japanese Unexamined Patent Publication No. 2006-83010

### DISCLOSURE OF THE INVENTION

### Problem to be Solved by the Invention

A ZnO thin film with a c-axis of a hexagonal system being oriented to be perpendicular to a thin film surface (such crystal orientation is referred to as c-axis orientation) is widely used as a piezoelectric thin film since 1970s. Depending on application or a type of a device (such as an SH type SAW device), there is sometimes required a ZnO thin film with the c-axis (a polarized direction) being oriented in parallel with the thin film surface (such a crystal orientation is referred to as c-axis in-plane orientation), particularly a ZnO thin film with the c-axes being parallel to the thin film surface and being aligned in one direction on the entire thin film. For this purpose, it is necessary that the c-axis be aligned to be parallel to the thin film surface during deposition of the ZnO thin film.

However, as described in paragraphs 0010 and 0026 of Patent Document 1, the ZnO thin film obtained by the technique of Patent Document 1 is c-axis oriented, that is, the c-axes are oriented to be perpendicular to the thin film surface. In the graph of X-ray diffraction results in FIG. 2 of Patent Document 1, a peak indicating the c-axis orientation in a (0002) plane appears prominently while a peak indicating the c-axis in-plane orientation does not appear.

In view of these circumstances, it is an object of the present invention to provide a thin film producing method in which a crystal thin film having a crystal structure of a hexagonal system can be deposited to be c-axis in-plane oriented.

### Means for Solving the Problem

In order to achieve such an object, a thin film producing method according to the present invention is for producing a thin film on a surface of a substrate by a sputtering method, and includes: disposing the substrate so as to face a particle source; causing an energetic particle emitted from the particle source to be incident on the substrate; causing the energetic particle to be incident on the surface of the substrate such that a predetermined crystal axis direction is parallel to the surface of the substrate; and forming a thin film including the energetic particle.

This thin film producing method is suitable for formation of a hexagonal thin film such as a piezoelectric thin film made of zinc oxide. Particularly, this thin film producing method is effectively used to obtain a thin film with a c-axis direction of the hexagonal system being parallel to a thin film surface and the c-axes being aligned in one direction. The particle source is sputtered to supply a constituent element of the thin film. For example, the particle source may be a sputtering target.

In preparing a thin film, a mean free path of the energetic particle emitted from the particle source is lengthened to cause a large amount of high-energy particles to be incident on the substrate when a pressure is lowered to thin a gas in the chamber. A hexagonal material has a close-packed plane in which surface energy is minimized in a (0001) plane. A thin film formed of the hexagonal material is c-axis oriented. Thus, when a small amount of energetic particles are incident on the substrate, the close-packed plane such as the (0001) plane of the hexagonal system is preferentially grown on the substrate. On the other hand, when a large amount of energetic particles are incident on the substrate, a crystal grain having the close-packed plane is probably damaged by collision of the energetic particles, thereby preventing growth of the crystal grain having the close-packed plane. As a result, a crystal plane having a channeling effect in which incidence of the energetic particles is slightly influenced, for example, a crystal grain having a (11-20) plane of the hexagonal system is preferentially grown to form an in-plane oriented film. Although such a growth mechanism is prominently exhibited in ZnO, it is also possible to apply a material other than ZnO. The orientation direction or an orientation fluctuation of the thin film formed on the substrate can be controlled by an incident direction or collimating property of the energetic particles.

In the thin film producing method according to the present invention, the mean free path of the energetic particle is lengthened by lowering the gas pressure, and the particle source is sputtered in a low-pressure atmosphere of 0.15 Pa or less (more preferably, 0.1 Pa or less) to emit the energetic particles or the substrate is disposed near the particle source in order that more energetic particles are incident on the substrate. Then, more of the energetic particles are incident on the substrate to form a thin film, so that a c-axis in-plane oriented thin film with the c-axis direction being oriented to be parallel to the thin film surface can be obtained on the entire surface of the substrate. The neighborhood of the particle source where the substrate is disposed sufficiently satisfies the condition as far as being located within a plasma region.

In this thin film producing method, the number of particle sources is not limited to one, but the thin film is formed by the energetic particles emitted from at least one particle source.

The thin film can be formed on the surface of the substrate by a reaction of the energetic particles emitted from the particle source and plasma gas particles.

In the thin film producing method according to the present invention, a thin film of high quality can be obtained by controlling an incident angle of the energetic particle to the substrate, an incident direction thereof, or spread of the incident direction thereof. Further, the incident angle of the energetic particle to the substrate, the incident direction thereof, or the spread of the incident direction thereof is controlled by placing a shield plate or a slit in a space between the substrate and the particle source, which allows a high-quality thin film to be obtained.

In the thin film producing method described above, although the thin film can be c-axis in-plane oriented on the entire surface of the substrate, sometimes the c-axes are not aligned in one direction due to the shape of a magnetic circuit (such as a circular magnetron circuit) and the c-axis direction becomes randomized on the entire surface of the substrate.

In a thin film producing method according to an embodiment of the present invention, a magnetic circuit is provided behind the particle source, and the thin film is formed on the surface of the substrate only by the energetic particles emitted from the particle source in a linear portion within a region with a high magnetic flux density of a magnetic field generated by the magnetic circuit. The sputtering method with use of such a magnetic circuit includes a magnetron sputtering method and is capable of improving the deposition rate. Further, in this embodiment, because the thin film is formed only by the energetic particles emitted from the particle source in the linear portion of the region with the high magnetic flux density, the c-axis direction also becomes random in the region where the thin film is formed by the energetic particles flying out of a plurality of positions of the particle source. However, in the region where the thin film is formed only by the energetic particles flying out of one single linear portion in the region with the high magnetic flux density, because the incident direction of the energetic particles are substantially uniformed, the c-axes thereof are aligned in one direction. Therefore, in the thin film obtained in this embodiment, the c-axis is in-plane oriented in the whole substrate, and the c-axes are aligned in one direction at least partially on the substrate. The thin film with the c-axis being in-plane oriented on the entire surface of the substrate and the c-axes being aligned in one direction on the entire surface of the substrate can be obtained depending on the position or dimensions of the substrate.

In a thin film producing method according to another embodiment of the present invention, a magnetic circuit is provided behind the particle source, and the thin film is formed on the surface of the substrate only by the energetic particles emitted from the particle source in a single linear portion of a region with a high magnetic flux density in a magnetic field generated by the magnetic circuit. In this embodiment, because the thin film is formed only by the energetic particles emitted from the particle source in the single linear portion of the region with the high magnetic flux density, the thin film is formed by the energetic particles flying from a substantially constant direction and being incident on any region of the substrate. As a result, in the thin film obtained according to this embodiment, the c-axis is in-plane oriented on the entire surface of the substrate, and the c-axes are aligned in one direction on the entire surface of the substrate.

In order that the thin film is formed only by the energetic particles emitted from the particle source in the single linear portion of the region with a magnetic flux density, the magnetic circuit may include one N pole and one S pole so as to generate a linear region with the high magnetic flux density only between the N pole and the S pole.

Alternatively, a partial region of the particle source may be covered with a shield plate so as to prevent the energetic particle emitted from the region of the particle source covered with the shield plate from reaching the surface of the substrate, and what reach the substrate are only the energetic particles emitted from the particle source in the single linear portion of the region with the high magnetic flux density in a region of the particle source not covered with the shield plate.

Further alternatively, a partial region of the particle source may be covered with a hardly-sputtered material so as to prevent the energetic particle emitted from the region of the particle source covered with the hardly-sputtered material from reaching the surface of the substrate, and what reach the substrate are only the energetic particles emitted from the particle source in the single linear portion of the region with the high magnetic flux density in a region of the particle source not covered with the hardly-sputtered material.

In the magnetic circuit in which one of an N pole and an S pole is disposed so as to be sandwiched from both sides between the other of the N pole and S pole, a hardly-sputtered material may be used as the particle source in one of regions between the N pole and the S pole. Because the energetic particle is not emitted from the hardly-sputtered material, the thin film is formed by the energetic particles emitted only from the remaining linear portion of the region with the high magnetic flux density.

In the magnetic circuit in which one of an N pole and an S pole is disposed so as to be sandwiched from both sides between the other of the N pole and S pole, the particle source may be provided only in one of regions between the N pole and S pole. Because the energetic particle is not emitted from the portion where the particle source does not exist, the thin film is formed by the energetic particles emitted only from the remaining linear portion of the region with the high magnetic flux density.

The substrate may be disposed so as to intersect always at a constant angle with one linear portion in the region with the high magnetic flux density.

Such a zinc-oxide thin film can be used in a piezoelectric element, a transducer, a SAW device, a thin film resonator (FBAR), and the like.

In the present invention, means for solving the problem has a feature of appropriate combination of the constituents described above, and various variations can be made in the present invention by such combination of the constituents. Further, the present invention can also be applied to formation of a piezoelectric thin film made of aluminum nitride, zinc oxide, or gallium nitride.

### BRIEF DESCRIPTION OF THE DRAWINGS

FIG. 1 is a schematic sectional view illustrating a structure of a magnetron sputtering apparatus according to a first embodiment of the present invention.

FIG. 2 is a view illustrating X-ray diffraction experiment results (XRD patterns) of a ZnO thin film deposited by the magnetron sputtering apparatus of the first embodiment and a ZnO thin film of a comparative example.

FIG. 3 is a view illustrating a state where a hexagonal ZnO crystal is oriented along a thin film surface.

FIG. 4 is a (11-22) pole figure of the ZnO thin film of the first embodiment.

FIG. 5 is a schematic sectional view illustrating a structure of a magnetron sputtering apparatus according to a second embodiment of the present invention.

FIG. 6 is a schematic transverse sectional view illustrating the magnetron sputtering apparatus of the second embodiment.

FIG. 7 is a view illustrating a shape of a substrate and positions on the substrate.

FIGS. 8(a), 8(b), and 8(c) are (11-22) pole figures of a ZnO thin film of the second embodiment.

FIG. 9 is a schematic sectional view illustrating a structure of a magnetron sputtering apparatus according to a third embodiment of the present invention.

FIG. 10 is a schematic transverse sectional view illustrating the magnetron sputtering apparatus of the third embodiment.

FIG. 11 is a view illustrating X-ray diffraction experiment results (XRD patterns) of a ZnO thin film of the third embodiment.

FIGS. 12(a), 12(b), and 12(c) are (11-22) pole figures of the ZnO thin film of the third embodiment.

FIG. 13 is a schematic transverse sectional view illustrating a modification of the third embodiment.

FIG. 14 is a schematic sectional view illustrating a structure of a magnetron sputtering apparatus according to a fourth embodiment of the present invention.

FIG. 15 is a schematic transverse sectional view illustrating the magnetron sputtering apparatus of the fourth embodiment.

FIG. 16 is a schematic sectional view illustrating a modification of the fourth embodiment.

FIG. 17 is a schematic sectional view illustrating a structure of a magnetron sputtering apparatus according to a fifth embodiment of the present invention.

FIG. 18 is a schematic transverse sectional view illustrating the magnetron sputtering apparatus of the fifth embodiment.

FIG. 19 is a schematic sectional view illustrating a structure of a magnetron sputtering apparatus according to a sixth embodiment of the present invention.

FIG. 20 is a schematic sectional view illustrating a structure of a magnetron sputtering apparatus according to a seventh embodiment of the present invention.

FIG. 21 is a schematic transverse sectional view illustrating the magnetron sputtering apparatus of the seventh embodiment.

FIG. 22 is a schematic sectional view illustrating a structure of a magnetron sputtering apparatus according to an eighth embodiment of the present invention.

FIG. 23 is a perspective view illustrating a SAW device according to the present invention.

FIG. 24 is a side view of the SAW device.

FIG. 25 is a schematic sectional view illustrating a transducer according to the present invention.

FIG. 26 is a schematic sectional view illustrating another transducer according to the present invention.

### DESCRIPTION OF SYMBOLS

21 Vacuum chamber
22 Target
23 Magnetron circuit
27 Substrate holder
28 Substrate
29 Power supply
30 Gas inflow port
31 Gas exhaust port
38 Plasma region
39 Erosion region
39a and 39b Longer-side portion of erosion region
39c and 39d Shorter-side portion of erosion region
40 Thin film surface
51 Shield plate
52 Horizontal plate portion
53 Vertical plate portion
61 Hardly-sputtered material
71 Shield plate
81 Magnetron circuit
85 ZnO thin film
86 IDT
87 Reflecting electrode
88 Antenna
91 Membrane
91b ZnO thin film
95 Cantilever
95b ZnO thin film
101 to 107 Magnetron sputtering apparatus
108 SAW device
109 and 110 Sensor

### BEST MODES FOR CARRYING OUT THE INVENTION

Embodiments of the present invention will be described in detail below with reference to the drawings.

### First Embodiment

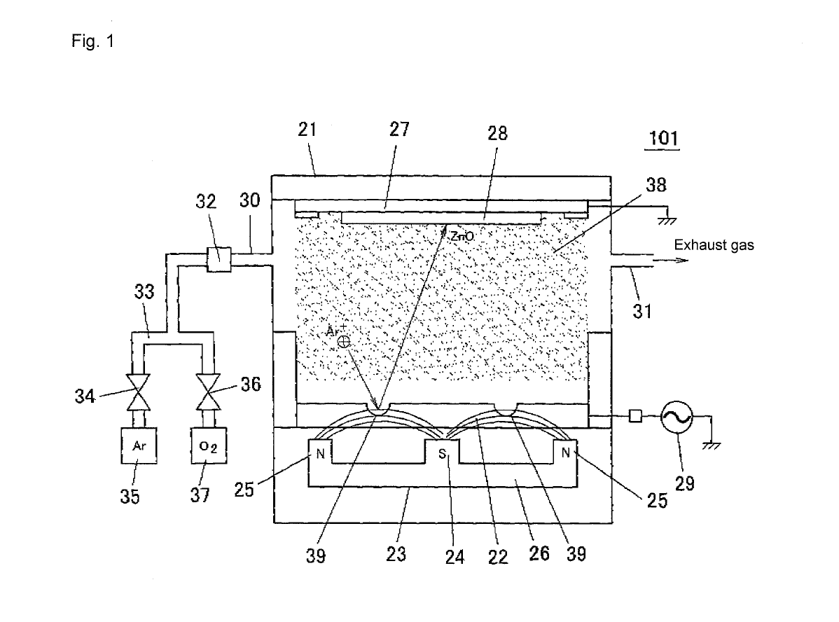

FIG. 1 is a schematic sectional view illustrating a structure of a magnetron sputtering apparatus 101 used to implement a thin film producing method according to a first embodiment of the present invention. In the magnetron sputtering apparatus 101, a disc-shaped target 22 (a particle source) made of a sintered ZnO is disposed in a lower portion of a vacuum chamber 21. A magnetron circuit 23 (a magnetic circuit) is provided on a lower surface of the target 22. The magnetron circuit 23 is of a type in a circular shape, and one of magnetic poles (hereinafter referred to as an S pole 24) located in the center and an annular magnetic pole (hereinafter referred to as an N pole 25) around the S pole 24 are coupled by a yoke 26, and a magnetic field (a magnetic flux) is generated between the S pole 24 and the N pole 25. A substrate holder 27 is provided in a ceiling portion of the vacuum chamber 21, and a thin-film forming substrate 28 is attachable to a lower surface of the substrate holder 27. A power supply 29 is provided between the target 22 and the substrate holder 27 so as to generate a high-frequency electric field.

A gas inflow port 30 and a gas exhaust port 31 are provided in the vacuum chamber 21. A gas supply pipe 33 branched into two is connected to the gas inflow port 30 with a mixed-gas flow control valve 32 interposed therebetween. An Ar gas supply source 35 is connected to one of the branched gas supply pipes 33 with a flow control valve 34 interposed therebetween, and an O₂ gas supply source 37 is connected to the other branched gas supply pipe 33 with a flow control valve 36 interposed therebetween.

In the first embodiment, a ZnO₂ thin film is deposited under the following conditions with use of the magnetron sputtering apparatus 101 described above.

RF power density: 2.5 W/cm²

deposition pressure: 0.1 Pa to 0.01 Pa

O₂/Ar ratio: 2

O₂ gas flow rate: 32 sccm

Ar gas flow rate: 16 sccm

The substrate 28 is fixed to the lower surface of the substrate holder 27 in the vacuum chamber 21. Although the type of the substrate 28 is not particularly limited, but an Si substrate or a Pyrex (registered trademark) glass substrate can be used as the substrate 28. During deposition, a plasma region 38 (a plasma post) is generated between the target 22 and the substrate holder 27. The substrate 28 is located within the plasma region 38, and the substrate 28 is located closer to the target 22 in comparison to usual cases. Thereafter, the vacuum chamber 21 is vacuumed to form a vacuum state therein, and the flow control valves 34 and 36 and the mixed-gas flow control valve 32 are opened to cause the Ar gas and the O₂ gas to flow into the vacuum chamber 21. In this case, a flow rate ratio of the O₂ gas and the Ar gas is adjusted to become 2:1 by controlling the flow control valves 34 and 36, and a mixed-gas flow rate is adjusted to become 48 sccm (the O₂ gas flow rate of 32 sccm and the Ar gas flow rate of 16 sccm) by controlling the mixed-gas flow control valve 32, thereby maintaining a deposition pressure (a gas pressure in the chamber) in a range of 0.1 Pa to 0.01 Pa. During the deposition, the power supply 29 is turned on to apply a high-frequency electric field corresponding to 2.5 W/cm² between the target 22 and the substrate holder 27.

When the high-frequency electric field is applied, there are formed a magnetic field and an electric field in the vacuum chamber 21, and the Ar gas and O₂ gas are ionized by the electric field to emit electrons. The electrons are moved by the electric field and magnetic field near the target 22 so as to draw toroidal curves, whereby plasma is generated near the target 22 to sputter the target 22. The sputtering particles (ZnO) sputtered from the target 22 form a unidirectional flow toward the substrate 28 in the plasma. The sputtering particles are incident on the surface of the substrate 28 to form a ZnO thin film on the surface of the substrate 28.

Because the plasma density is increased in the region with a magnetic flux density maximized by the magnetron circuit 23, positive ions concentrically collide with the target 22 in this region, and the sputtering particles are sputtered from the target 22. Because erosion of the target 22 occurs in the region with the maximized magnetic flux density, hereinafter the region where the erosion of the target 22 is caused is referred to as an erosion region 39. The sputtering particles flying out of the erosion region 39 are incident on the surface of the substrate 28 to form a ZnO thin film on the surface of the substrate 28.

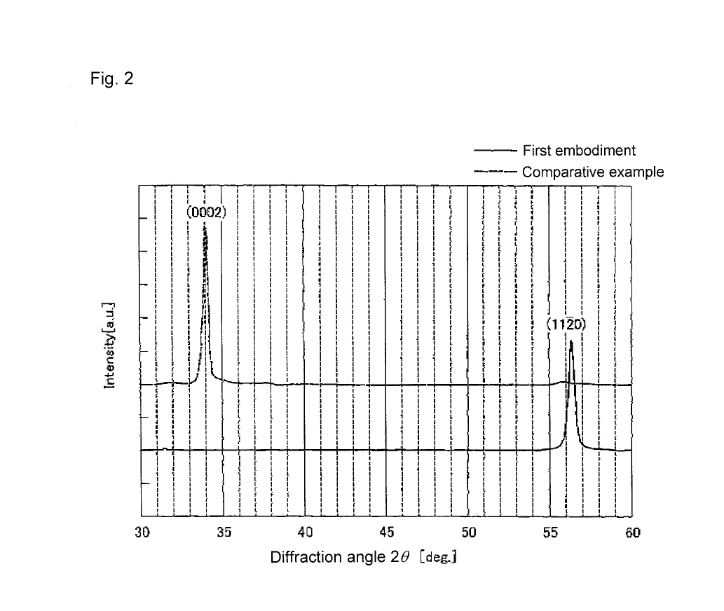

FIG. 2 is a graph of X-ray diffraction experiment results (XRD patterns) of the ZnO thin film (of the first embodiment) deposited by the magnetron sputtering apparatus 101 and a ZnO thin film of a comparative example. In FIG. 2, a horizontal axis indicates a diffraction angle 2θ of an irradiation X-ray and a vertical axis indicates an X-ray diffraction intensity (in an arbitrary scale). The ZnO thin film of the comparative example is deposited with the substrate disposed distant from the plasma region 38.

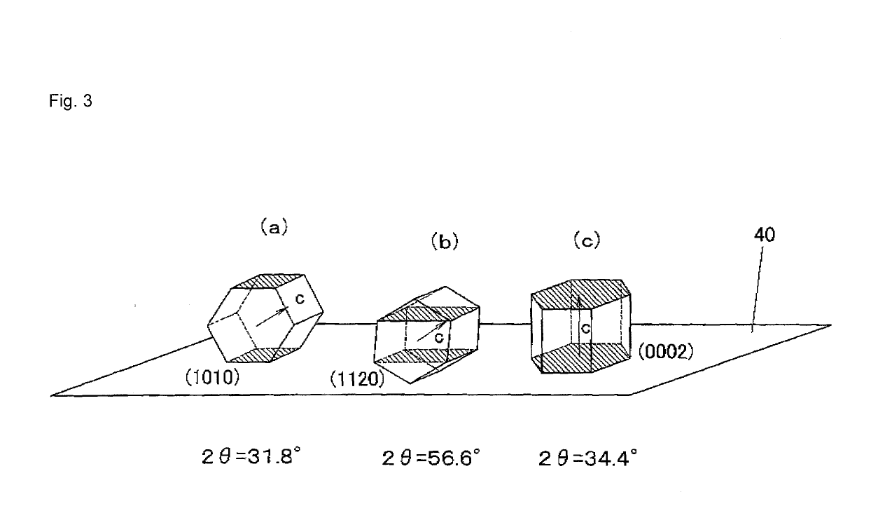

FIGS. 3(a), 3(b), and 3(c) illustrate states where the hexagonal ZnO crystal is oriented. FIG. 3(c) illustrates the c-axis oriented ZnO crystal with the c-axis being oriented to be perpendicular to a thin film surface 40 and a (0001) plane of the ZnO crystal is aligned with the thin film surface 40. In this case, in the X-ray diffraction experiment, an intensity peak of a (0002) plane appears around the diffraction angle 2θ=34.4°. As illustrated in FIGS. 3(a) and 3(b), there are two patterns of the c-axis in-plane orientation. In FIG. 3(a), a (10-10) plane of the ZnO crystal is c-axis in-plane oriented while being aligned with the thin film surface 40. In such a case, in the X-ray diffraction experiment, the intensity peak appears around the diffraction angle 2θ=31.8°. In FIG. 3(b), a (11-20) plane of the ZnO crystal is c-axis in-plane oriented while being aligned with the thin film surface 40. In such a case, in the X-ray diffraction experiment, the intensity peak appears around the diffraction angle 2θ=56.6°.

According to the X-ray diffraction experiment of FIG. 2, in the ZnO thin film of the comparative example, a peak of the (0002) plane indicating the c-axis orientation appears prominently and no peak indicating the c-axis in-plane orientation appears. To the contrary, in the ZnO thin film of the first embodiment, a peak of the (11-20) plane indicating the c-axis in-plane orientation appears prominently, and no peak indicating the c-axis orientation appears. Accordingly, the vacuum chamber 21 is highly vacuumed and the substrate 28 is placed in the plasma region 38 and is brought closer to the target 22, thereby obtaining a c-axis in-plane oriented ZnO thin film on the entire surface of the substrate 28.

In preparing the ZnO thin film on the substrate 28, the mean free path of the sputtering particle emitted from the target 22 is lengthened to cause a large amount of high-energy sputtering particles to be incident on the substrate 28 because the gas pressure is lowered in the chamber 21. When a small amount of high-energy sputtering particles are incident, the (0001) plane as a close-packed plane is preferentially grown on the substrate 28. On the other hand, growth (c-axis orientation) of the crystal grain on the (0001) plane as the close-packed plane is suppressed when a large amount of high-energy sputtering particles are incident on the substrate 28. As a result, the crystal plane slightly influenced by incidence of the high-energy sputtering particles, that is, the crystal grain having the (11-20) plane (a channeling effect) is preferentially grown to form a c-axis in-plane oriented film. The orientation direction or orientation fluctuation of the thin film can be controlled by the incident direction or collimating property of the sputtering particle.

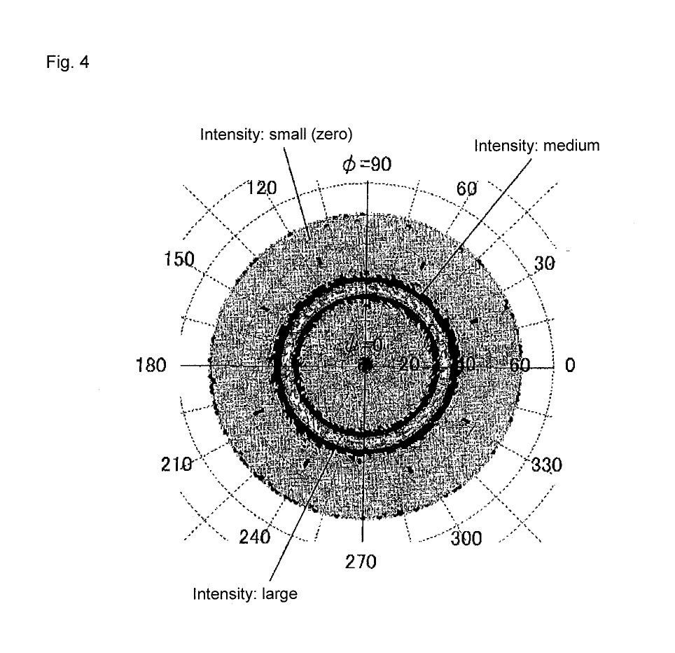

A (11-22) pole figure is formed using the ZnO thin film of the first embodiment and the result illustrated in FIG. 4 is obtained. According to the (11-22) pole figure of FIG. 4, in the ZnO thin film of the first embodiment, although the (11-20) plane is c-axis in-plane oriented, the c-axes thereof are not aligned in a constant direction but are randomly oriented. This is because of the fact that the flying directions of the ZnO particles are changed depending on positions with use of the magnetron circuit 23 of the circular type.

In the (11-22) pole figure of FIG. 4, the X-ray incident angle is fixed to 33.98° (2θ=67.96° that is the diffraction condition for the (11-22) plane in a case where an elevation angle ψ of the thin film is set to 0°, and the detected intensity of the X-ray diffraction is mapped by scanning the elevation angle ψ and an azimuth angle φ of the thin film. As indicated in FIG. 4, the intensity is the lowest (the intensity equal to zero) in a gray region, a black region has the medium intensity, and a white region has the highest intensity. According to this pole figure, the pole of the (11-22) plane is concentrically distributed at any azimuth angle φ in the elevation angle ψ of about 32° that is equal to the angle formed by the (11-20) plane and the (11-22) plane, and the c-axes are randomly oriented in the plane parallel to the thin film surface.

As in the first embodiment, when the substrate is placed in the plasma region and is brought closer to the target 22 with the vacuum chamber being highly vacuumed, the sputtering particle flying out of the target 22 hardly will collide with other sputtering particles or a gas, and a large amount of sputtering particles will be incident on the substrate 28 from a substantially constant direction so as to be c-axis in-plane oriented on the surface of the substrate. On the other hand, in a case where the magnetron circuit 23 of the circular type is used, because the incident directions of the sputtering particles to the substrate 28 are changed depending on positions, the c-axes will not be aligned in one direction but be randomized in the entire substrate.

### Second Embodiment

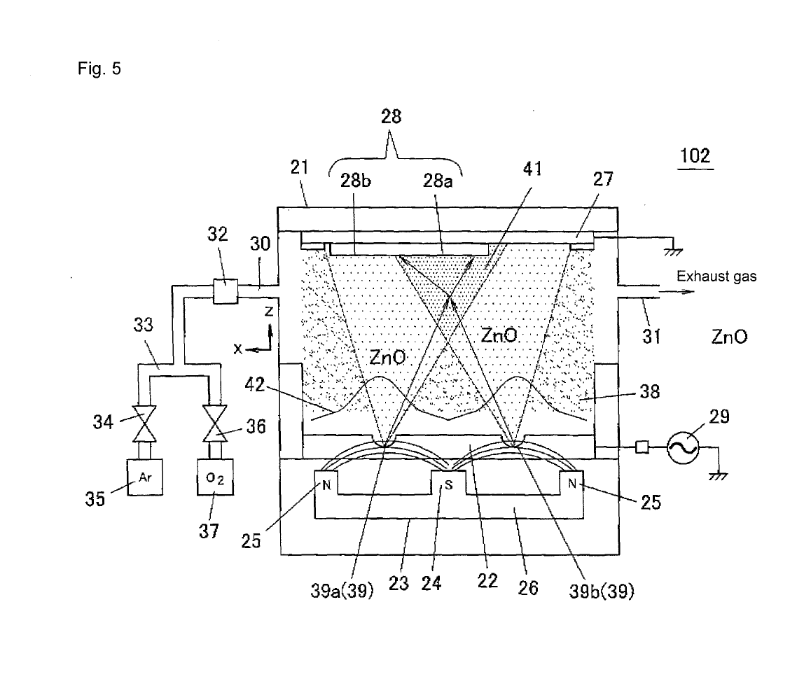

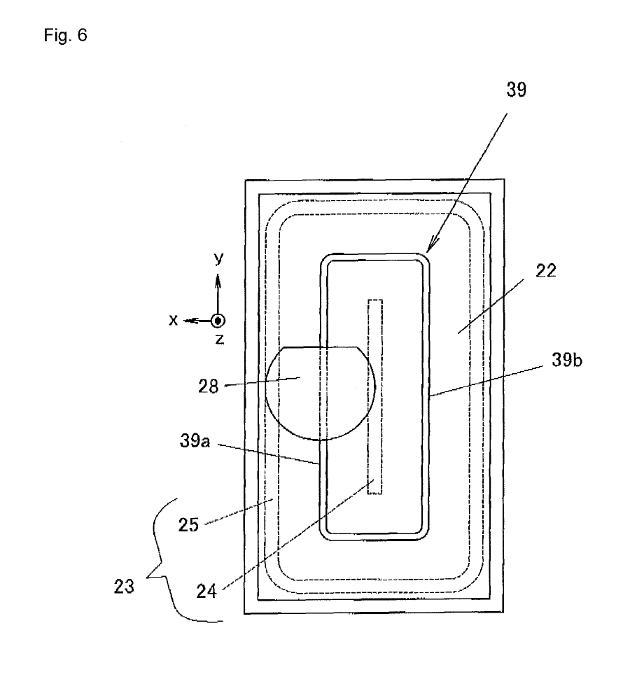

FIG. 5 is a schematic sectional view illustrating a structure of a magnetron sputtering apparatus 102 used to implement a thin film producing method according to a second embodiment of the present invention. The magnetron sputtering apparatus 102 of the second embodiment has the structure similar to that of the magnetron sputtering apparatus 101 of the first embodiment, and the same component is designated by the same symbol. In the magnetron sputtering apparatus 102 of the second embodiment, the magnetron circuit 23 of a rectangular type and the rectangular target 22 are used as illustrated in FIG. 6.

As illustrated in FIG. 6, the magnetron circuit 23 is formed into the rectangular shape and includes the S pole 24, the N pole 25, and the yoke 26. The S pole 24 is disposed in a central portion. The N pole 25 is formed into the rectangular shape so as to surround the S pole 24. The yoke 26 couples the S pole 24 with the N pole 25. In the N pole 25, at least two sides facing each other have a linear length sufficiently longer than a diameter of the substrate 28. The target 22 is made of a sintered ZnO into the rectangular shape in accordance with the magnetron circuit 23. In the magnetron sputtering apparatus 102 using the magnetron circuit 23 of the rectangular type, the substrate 28 is disposed above the portion where the N pole 25 is linearly extended.

Hereinafter, a lengthwise direction of the N pole 25 in the region for disposing the substrate 28 is referred to as a y direction, a horizontal direction in a surface perpendicular to the y direction is referred to as an x direction, and a vertical direction is referred to as a z direction.

The deposition conditions are identical to those of the first embodiment.

RF power density: 25 W/cm²

deposition pressure: 0.1 Pa to 0.01 Pa

O₂/Ar ratio: 2

O₂ gas flow rate: 32 sccm

Ar gas flow rate: 16 sccm

The substrate 28 is disposed at a level to be included in the plasma region 38.

In the region where the N pole 25 of the magnetron circuit 23 is linearly extended, because the magnetic field generated between the S pole 24 and the N pole 25 exists in a plane (a zx plane) perpendicular to the lengthwise direction of the N pole 25, the flying directions of the sputtering particles flying out of the erosion region 39 are included substantially in the zx plane, and the sputtering particles are hardly spread in the y direction. However, because the ZnO particles flying out of the erosion region 39 are largely spread in the zx plane as illustrated in FIG. 5, there is generated, above a central portion between the right side and the left side of the erosion region 39 in the drawing (hereinafter, referred to as longer-side portions 39a and 39b), a region 41 where the sputtering particles flying out of the right and left erosion regions 39 are mixed together. The sputtering particles flying from random directions are incident on the surface of the substrate 28, whereby a randomly-oriented ZnO polycrystal is grown on the surface of the substrate 28.

As illustrated in FIG. 5, a distribution density 42 of the sputtering particles flying out of the longer-side portions 39a and 39b in the right side and the left side of the erosion region 39 is increased in the direction (the z direction) located immediately above the longer-side portions 39a and 39b, and is decreased as inclinations are increased from the direction located immediately thereabove.

Accordingly, in the second embodiment, when the substrate is disposed in the direction immediately above the erosion region 39, the substrate 28 is brought close to the target 22 to an extent in which the substrate is not located in the mixed region 41, and the substrate 28 is disposed to be inclined from the center of the target 22 toward the x direction (in the direction retreating from the other erosion region).

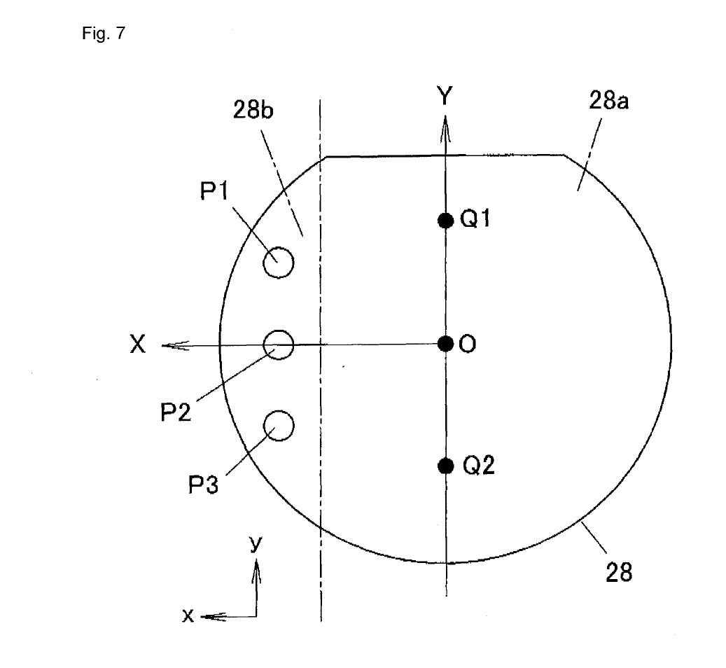

When the ZnO thin film is deposited on the surface of the substrate 28 using the magnetron sputtering apparatus 102, the c-axis in-plane oriented thin film with the c-axes being randomly oriented is formed in a region 28a located in the mixed region 41 on the surface of the substrate 28 illustrated in FIG. 7. On the other hand, in a region 28b on which only the sputtering particles flying out of the longer-side portion 39a in the erosion region 39 are incident, because the sputtering particles fly from a substantially constant direction to be incident on the surface of the substrate 28, a c-axis in-plane oriented ZnO thin film with the c-axes being aligned in one direction is obtained in the entire region. Therefore, according to the second embodiment, although the thin film 28 is c-axis in-plane oriented on the entire substrate, the region where the c-axes are aligned in one direction can be obtained only partially on the substrate 28.

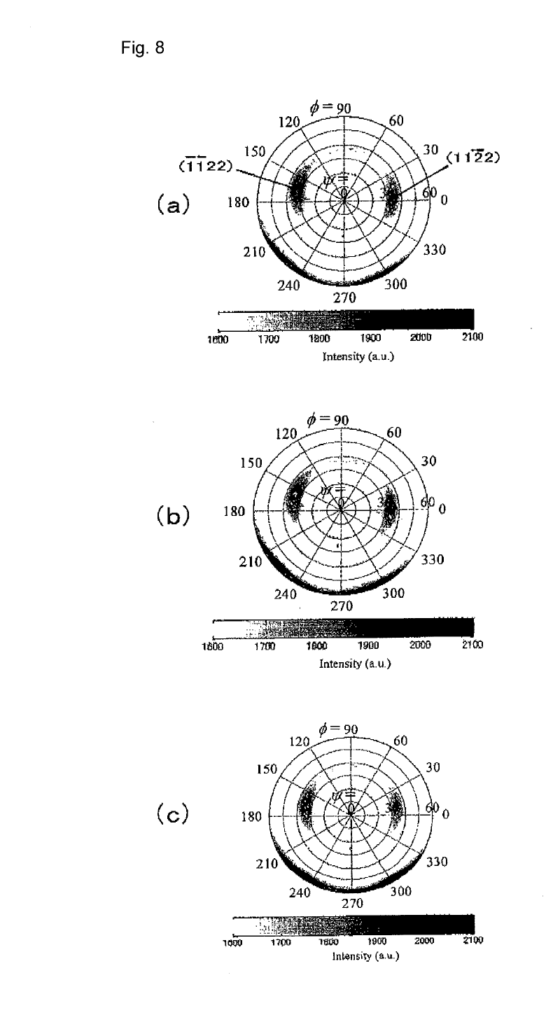

FIGS. 8(a), 8(b), and 8(c) illustrate results, using the ZnO thin film sample of the second embodiment deposited as described above, of the (11-22) pole figure of the ZnO thin film formed in the region 28b on which only the ZnO particles flying out of the longer-side portion 39a in the erosion region 39 are incident. FIGS. 8(a), 8(b), and 8(c) are the (11-22) pole figures of three points along the y direction. FIG. 8(a) is the (11-22) pole figure at a point P1 of FIG. 7, FIG. 8(b) is the (11-22) pole figure at a point P2 of FIG. 7, and FIG. 8(c) is the (11-22) pole figure at a point P3 of FIG. 7. According to these (11-22) pole figures, intensity distributions of the (11-22) plane pole and a (−1-122) plane pole are concentrated in the neighborhoods of the azimuth angles φ of 0° and 180° in the direction of the elevation angle ψ of substantially 32° that is equal to the angle formed by the (11-20) plane and the (11-22) plane, the c-axes of the ZnO thin film are oriented in-plane in one direction connecting the azimuth angles φ of 0° and 180°, and the ZnO thin film is c-axis in-plane oriented is in the (11-20) plane. In the pole figures of FIGS. 8(a), 8(b), and 8(c), intensity distributions are concentrated in a substantially same azimuth angle φ, the ZnO thin film is c-axis in-plane oriented in the (11-20) plane and the c-axes are aligned in a same direction in the entire part of a partial region of the substrate.

### Third Embodiment

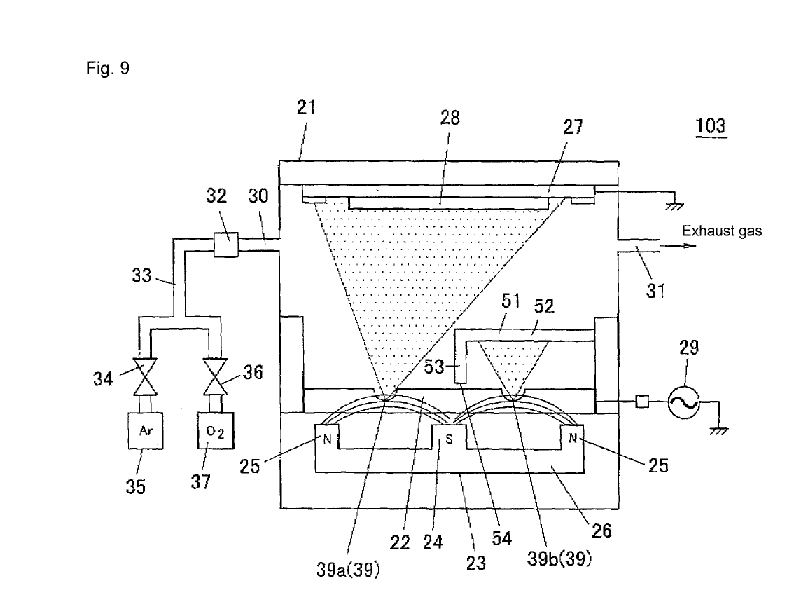

FIG. 9 is a schematic sectional view illustrating a structure of a magnetron sputtering apparatus 103 used to implement a thin film producing method according to a third embodiment of the present invention. The magnetron sputtering apparatus 103 of the third embodiment has the structure similar to that of the magnetron sputtering apparatus 102 of the second embodiment, and includes the magnetron circuit 23 of the rectangular type.

The deposition conditions are identical to those of the second embodiment.

RF power density: 2.5 W/cm²

deposition pressure: 0.1 Pa to 0.01 Pa

O₂/Ar ratio: 2

O₂ gas flow rate: 32 sccm

Ar gas flow rate: 16 sccm

The substrate 28 is disposed at a level to be included in the plasma region 38.

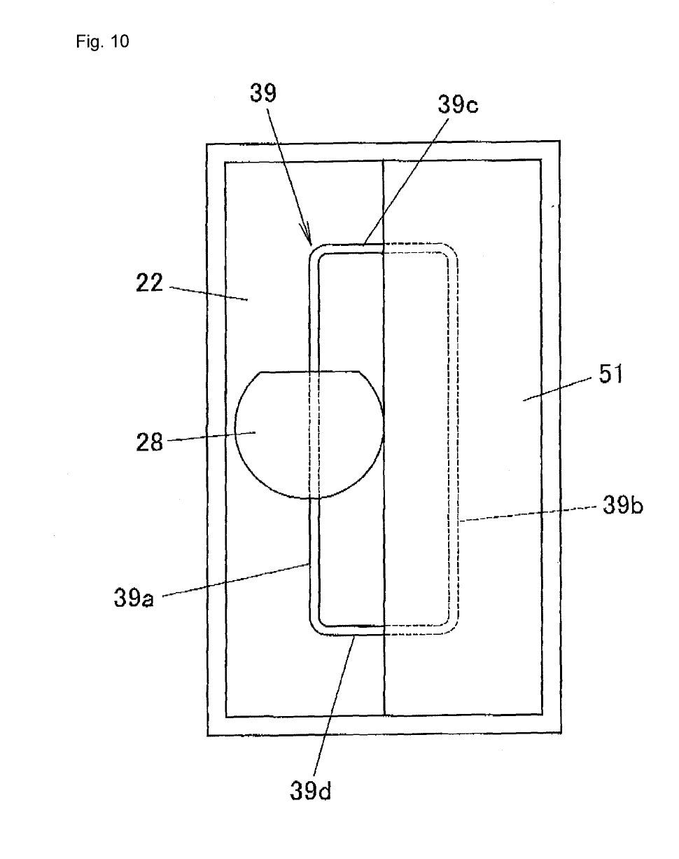

The magnetron sputtering apparatus 103 of the third embodiment is characterized in that one of the longer-side portions 39a and 39b facing in parallel with each other in the erosion region 39 is covered, while being spaced apart therefrom, with a shield plate 51 that is made of a non-magnetic metal. Specifically, as illustrated in FIG. 10, the shield plate 51 is provided above a half of the target 22, and the entire longer-side portion 39b in the erosion region 39 and halves of the shorter-side portions 39c and 39d are covered with the shield plate 51.

In the magnetron sputtering apparatus 103, because the longer-side portion 39b in the erosion region 39 is covered with the shield plate 51, there is generated a high-frequency electric field between the shield plate 51 and the target 22 located therebelow when the power supply 29 is turned on, and the sputtering particles flying out of the longer-side portion 39b in the erosion region 39 collide with the lower surface of the shield plate 51. Therefore, the sputtering particle flying out of the longer-side portion 39b is not incident on the surface of the substrate 28.

On the other hand, outside the shield plate 51, there is generated a high-frequency electric field between the target 22 and the substrate holder 27, and the sputtering particles fly out of the longer-side portion 39a located outside the shield plate 51 to be incident on the surface of the substrate 28.

In a case of using the magnetron circuit 23 of the rectangular type, the sputtering particles fly out of the erosion region 39 in the direction substantially in the zx plane, and the sputtering particles are hardly spread in the y direction. Further, in the third embodiment, the sputtering particles flying to the substrate 28 in the zx plane are sputtered only from the single erosion region 39 (the longer-side portion 39a) exposed from the shield plate 51, and the vacuum chamber 21 is maintained to be highly vacuumed so as to decrease a probability of collision between the sputtering particles as well as a probability of collision between one of the sputtering particles and a gas. Therefore, the sputtering particles flying out of the single longer-side portion 39a in a substantially constant direction are incident on the surface of the substrate 28. As a result, a c-axis in-plane oriented ZnO thin film with the c-axes being aligned in a same direction is obtained on the entire surface of the substrate 28.

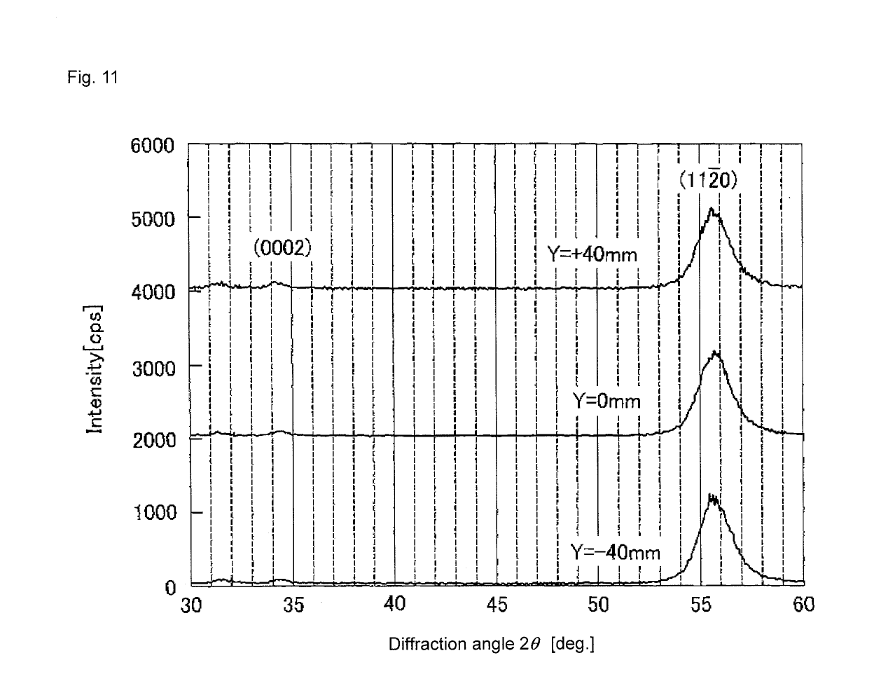

FIG. 11 is a graph of the X-ray diffraction experiment results (XRD patterns) of the ZnO thin film deposited by the magnetron sputtering apparatus 103 of the third embodiment. In FIG. 11, the horizontal axis indicates the diffraction angle 2θ of the incident X-ray, and the vertical axis indicates the X-ray diffraction intensity. FIG. 11 illustrates three X-ray diffraction intensities of the ZnO thin film respectively at a position of Y=+40 mm in the y direction from a center O of the substrate 28 (a point Q1 on the substrate of FIG. 7), a position of Y=0 mm (the point O on the substrate of FIG. 7), and a position of Y=−40 mm (a point Q2 on the substrate of FIG. 7). As can be seen from the three X-ray diffraction intensities, a peak of the (0002) plane is slightly observed around the diffraction angle 2θ=34.4° by the c-axis orientation, and a large peak of the (11-20) plane is observed around the diffraction angle 2θ=56.5° by the c-axis in-plane orientation.

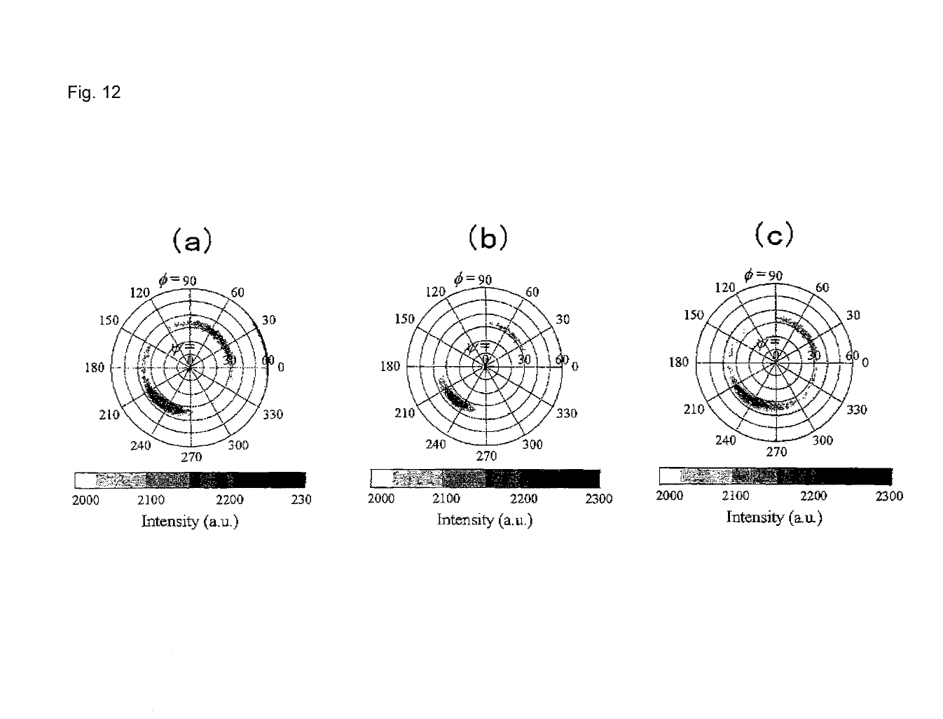

FIGS. 12(a), 12(b), and 12(c) are (11-22) pole figures of the ZnO thin film deposited by the magnetron sputtering apparatus 103 of the third embodiment. FIG. 12(a) illustrates the (11-22) pole figure at the point of Y=+40 mm from the center O of the substrate 28, FIG. 12(b) illustrates the (11-22) pole figure at the point of Y=0 mm from the center O of the substrate 28, and FIG. 12(c) illustrates the (11-22) pole figure at the point of Y=−40 mm from the center O of the substrate 28. According to these (11-22) pole figures, the intensity distributions are concentrated in a substantially same azimuth angle φ in the direction of the elevation angle ψ of 32°, and the ZnO thin film is c-axis in-plane oriented in the (11-20) plane with the c-axes thereof being aligned in a same direction.

In the illustrated example, the shield plate 51 is formed into a reverse L-shape in section by a horizontal plate portion 52 and a vertical plate portion 53, and there is provided a gap 54 between a lower end of the vertical plate portion 53 and the upper surface of the target 22 in order to cause a gas to flow therethrough. Although the shield plate 51 may include only the horizontal plate portion 52, the shield plate 51 may include the horizontal plate portion 52 and the vertical plate portion 53 to wrap the longer-side portion 39b, so that the sputtering particles sputtered from the longer-side portion 39b hardly leak from the space in the shield plate 51.

Instead of the shield plate 51, there may be provided a slit to cause only the sputtering particles flying out of the longer-side portion 39a to pass therethrough.

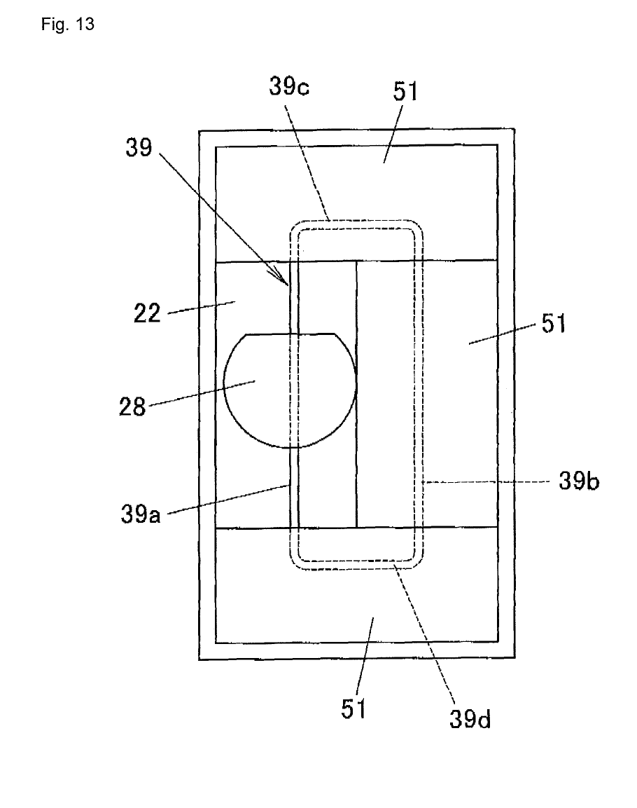

FIG. 13 is a schematic transverse sectional view illustrating a modification of the third embodiment. In this modification, the longer-side portion 39b in the substantially rectangular erosion region 39 and the shorter-side portions 39c and 39d facing each other are covered with the shield plate 51, and the shield plate 51 is disposed in a U-shape in planar view. According to the modification, the sputtering particles flying out of the shorter-side portions 39c and 39d in the erosion region 39 can be blocked so as not to fly toward the substrate 28, and the c-axes of the c-axis in-plane oriented ZnO thin film can be further aligned on the surface of the substrate 28.

### Fourth Embodiment

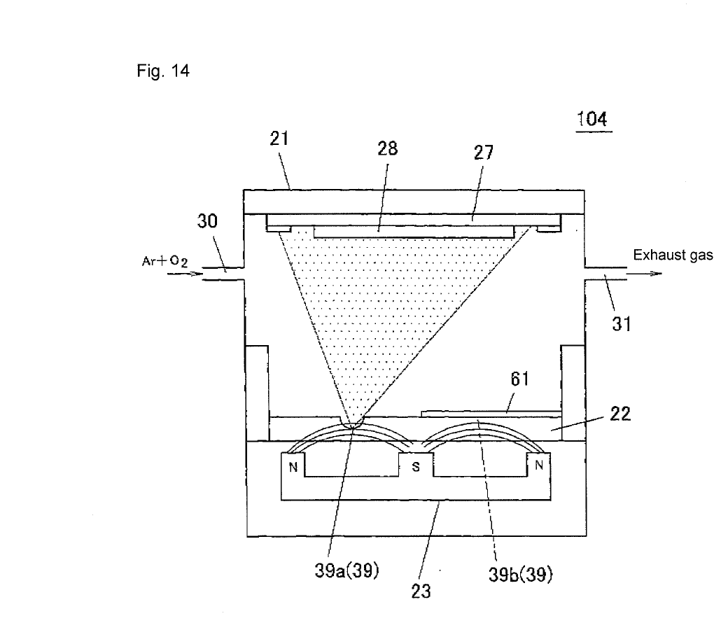

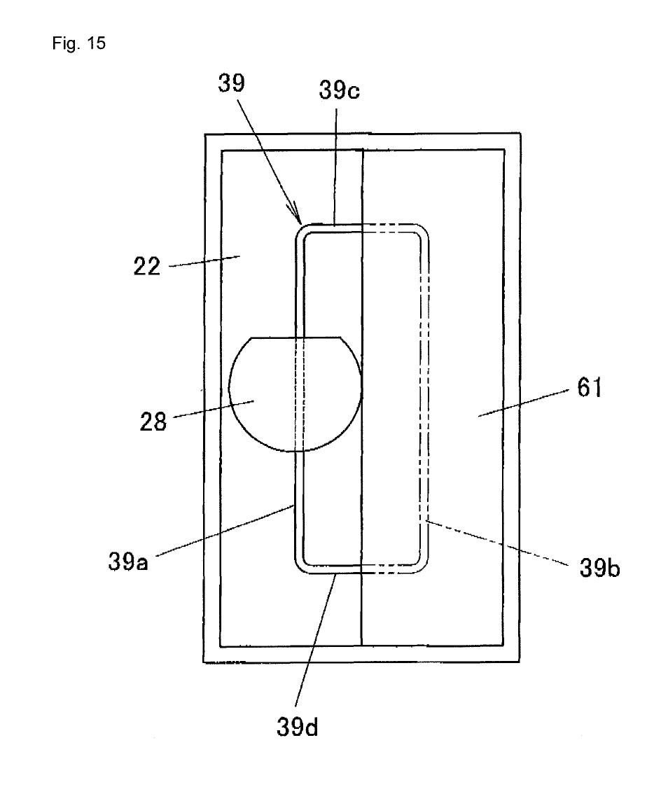

FIG. 14 is a schematic sectional view illustrating a structure of a magnetron sputtering apparatus 104 used to implement a thin film producing method according to a fourth embodiment of the present invention, and FIG. 15 is a schematic transverse sectional view of the magnetron sputtering apparatus 104. The magnetron sputtering apparatus 104 of the fourth embodiment has the structure similar to that of the second embodiment, and includes the magnetron circuit 23 of the rectangular type. In FIG. 14, the gas supply system and the power supply are not illustrated (the same holds true in the following embodiments).

In the fourth embodiment, as illustrated in FIG. 15, a hardly-sputtered material 61 is laminated on a half of the upper surface of the target 22 so as to cover the longer-side portion 39b in the erosion region 39. A hard material, such as alumina, carbon, or stainless steel which is hardly sputtered may be used as the hardly-sputtered material 61. Alternatively, an insulative material may be used as the hardly-sputtered material 61 while a direct-current power supply is adopted as the power supply 29. When a direct-current electric field is applied between the target 22 and the substrate holder 27 and the half of the target 22 is covered with the hardly-sputtered material 61 that is made of an insulative material, positive ions incident on the hardly-sputtered material 61 are charged up so as to stop discharge on the side covered with the hardly-sputtered material 61, resulting in that the hardly-sputtered material 61 is not sputtered.

In the magnetron sputtering apparatus 104, the longer-side portion 39b in the erosion region 39 is covered with the hardly-sputtered material 61 and the substrate 28 is disposed above the remaining longer-side portion 39a. Therefore, only the sputtering particles sputtered from the longer-side portion 39a that is not covered with the hardly-sputtered material 61 are incident on the surface of the substrate 28. As a result, for the reason similar to the third embodiment, the ZnO particles flying out of the single longer-side portion 39a in a substantially constant direction are incident on the surface of the substrate 28, and a c-axis in-plane oriented ZnO thin film with the c-axes being aligned in a same direction is obtained on the entire surface of the substrate 28.

Although not illustrated, there is obtained also in the fourth embodiment a (11-22) pole figure similar to that of FIG. 12 according to the third embodiment.

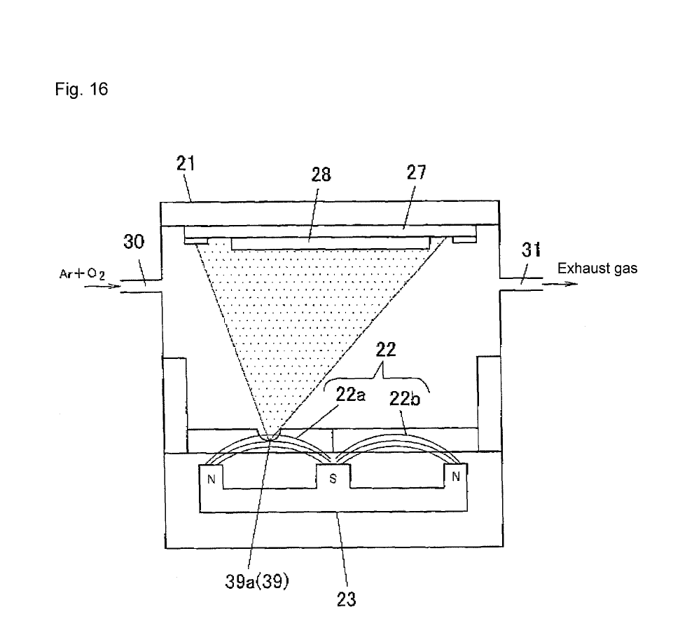

FIG. 16 illustrates a modification of the fourth embodiment. Instead of covering the half of the target 22 with the hardly-sputtered material 61, the target 22 is divided into two, namely a target 22a made of a sintered ZnO and a hardly-sputtered material 22b. The operational effect similar to that of the fourth embodiment can be obtained using the above target 22, and a c-axis in-plane oriented ZnO thin film with the c-axes being aligned in a same direction can be obtained on the entire surface of the substrate 28.

### Fifth Embodiment

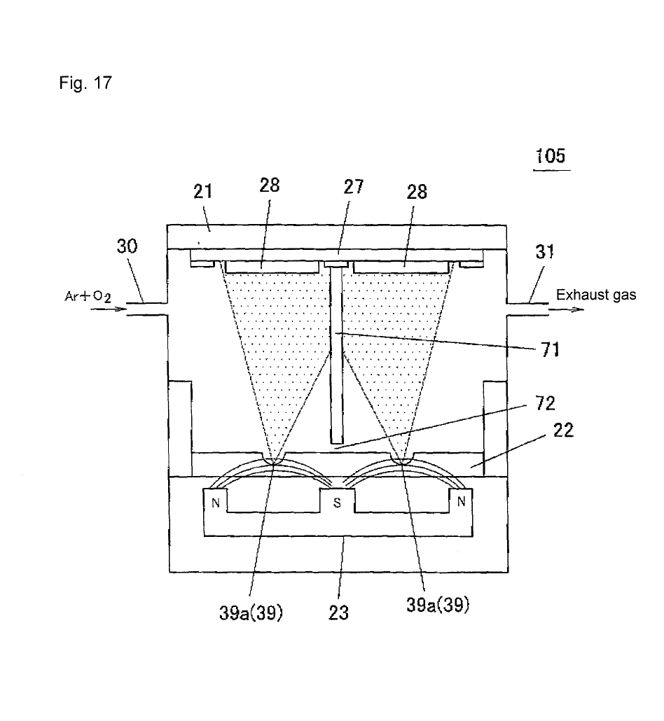

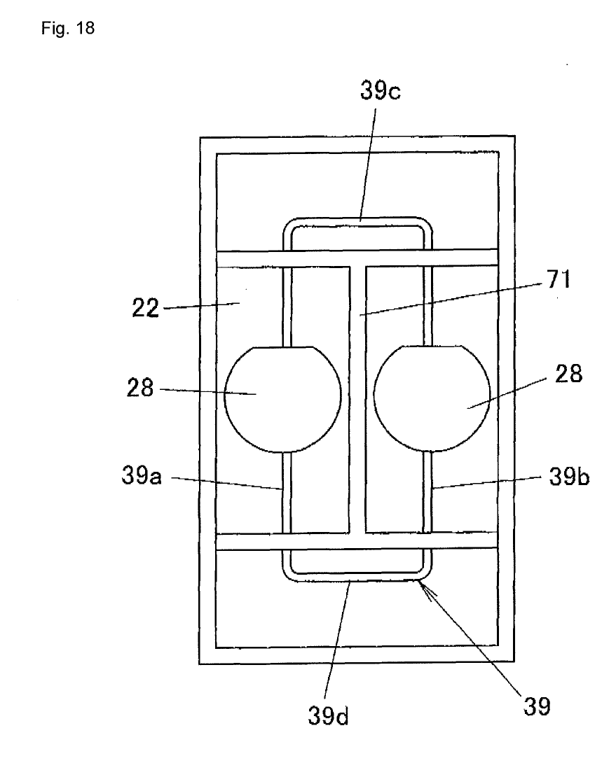

FIG. 17 is a schematic sectional view illustrating a structure of a magnetron sputtering apparatus 105 used to implement a thin film producing method according to a fifth embodiment of the present invention, and FIG. 18 is a schematic transverse sectional view of the magnetron sputtering apparatus 105. This magnetron sputtering apparatus 105 also has the structure similar to that of the magnetron sputtering apparatus 102 of the second embodiment, and includes the magnetron circuit 23 of the rectangular type.

In the fifth embodiment, a shield plate 71 is disposed in the vacuum chamber 21, while a plurality of vertical partitions are combined into an H-shape in planar view in the shield plate 71. The longer-side portions 39a and 39b in the rectangular erosion region 39 as well as the shorter-side portions 39c and 39d are respectively partitioned by the shield plate 71. The substrates 28 are respectively disposed above the longer-side portions 39a and 39b in the erosion region 39. An upper end of the shield plate 71 is preferably extended at least above a level of the substrates 28 thus disposed. A gas circulating gap 72 is provided between a lower end of the shield plate 71 and the upper surface of the target 22.

In the magnetron sputtering apparatus 105, the sputtering particles sputtered from the longer-side portion 39a (or 39b) fly up to the substrate 28 disposed in the longer-side portion 39a (or 39b) in the erosion region 39, while the sputtering particles sputtered from the remaining longer-side portion 39b (or 39a) do not reach the substrate 28 because the sputtering particles are blocked by the shield plate 71. As a result, for the reason similar to that of the third embodiment, the sputtering particles flying out of the single longer-side portion 39a in a substantially constant direction are incident on the surface of the substrate 28, and a c-axis in-plane oriented ZnO thin film with the c-axes being aligned along a same direction is obtained on the entire surface of the substrate 28. In the magnetron sputtering apparatus 105, the ZnO thin films can be deposited respectively by the two longer-side portions 39a and 39b in the erosion region 39, so that a throughput of the ZnO thin film producing process can be improved.

### Sixth Embodiment

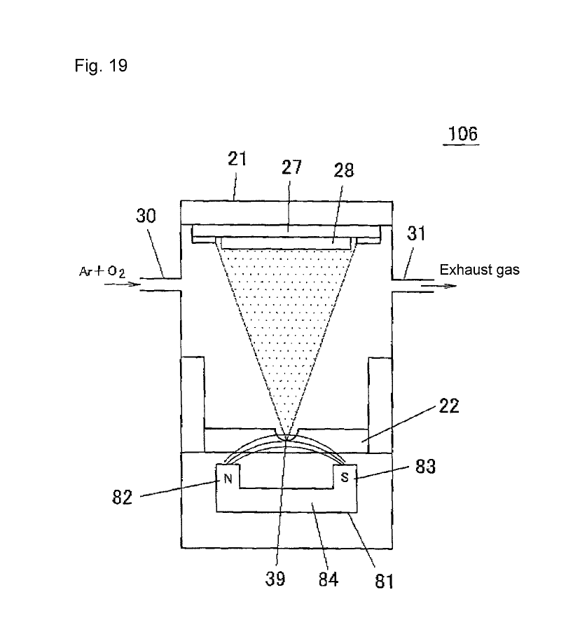

FIG. 19 is a schematic sectional view illustrating a structure of a magnetron sputtering apparatus 106 used to implement a thin film producing method according to a sixth embodiment of the present invention. This magnetron sputtering apparatus 106 has the structure similar to that of the second embodiment, and includes the magnetron circuit 23 of the rectangular type.

The magnetron sputtering apparatus 106 is characterized by a magnetron circuit 81. In the magnetron circuit 81, a linearly-extended N pole 82 and a linearly-extended S pole 83 are disposed in parallel with each other, and the N pole 82 and the S pole 83 are coupled by a yoke 84.

Only one linearly-extended erosion region 39 is generated in the magnetron sputtering apparatus 106. Accordingly, for the reason similar to that of the third embodiment, the ZnO particles flying out of the single erosion region 39 in a substantially constant direction are incident on the surface of the substrate 28, and a c-axis in-plane oriented ZnO thin film with the c-axes being aligned along a same direction is obtained on the entire surface of the substrate 28.

### Seventh Embodiment

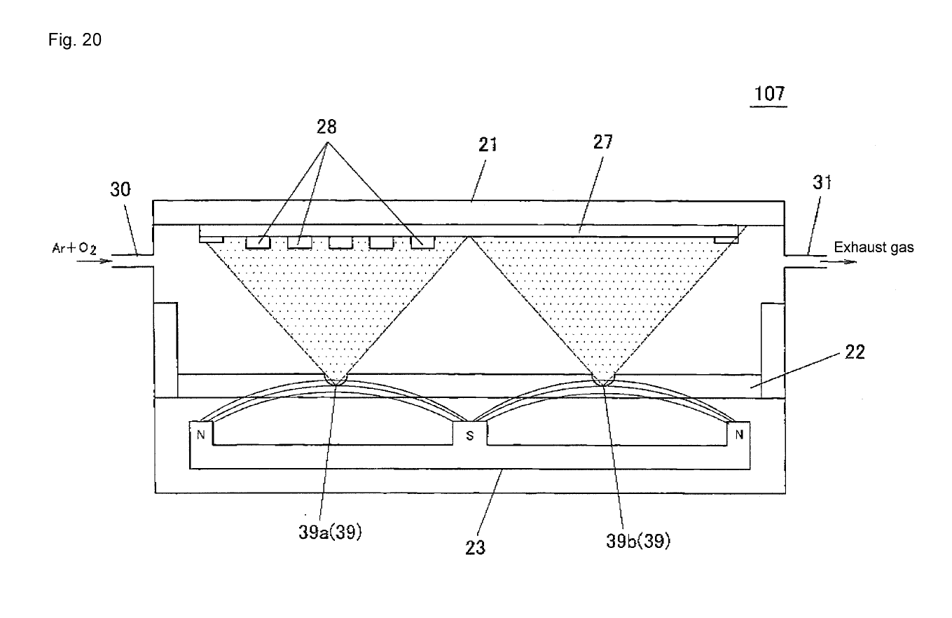

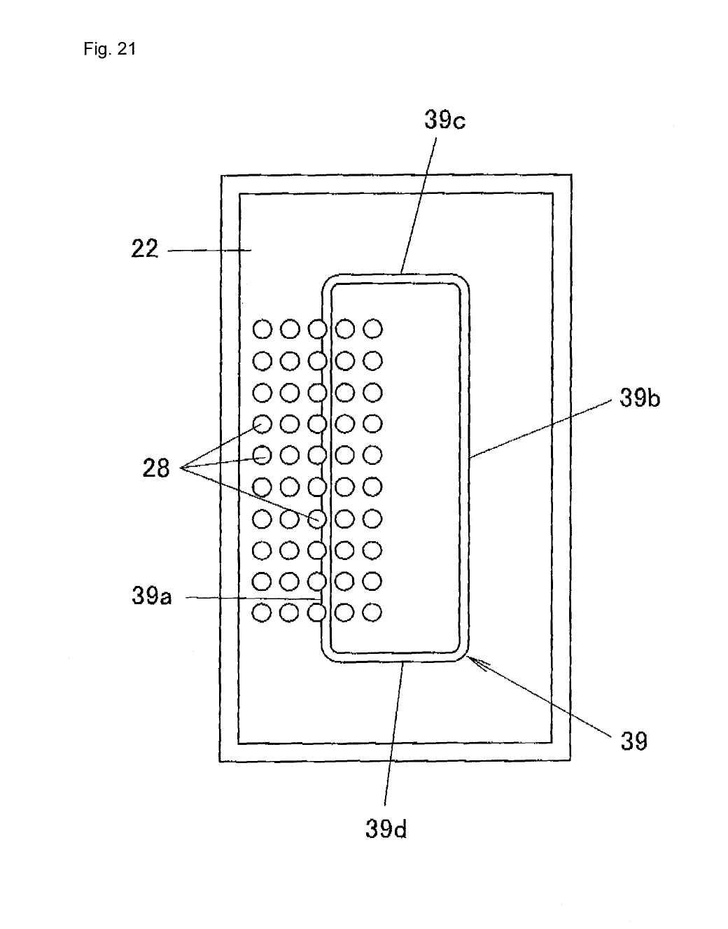

FIG. 20 is a schematic sectional view illustrating a structure of a magnetron sputtering apparatus 107 used to implement a thin film producing method according to a seventh embodiment of the present invention, and FIG. 21 is a schematic transverse sectional view of the magnetron sputtering apparatus 107. The magnetron sputtering apparatus 107 includes the target 22 that is extremely larger than the diameter of the substrate 28, and the magnetron circuit 23 of a large rectangular type in accordance with the large target 22.

In the large magnetron sputtering apparatus 107, the region where the sputtering particles flying out of the parallel longer-side portion 39a and 39b in the erosion region 39 are not mixed together has an area sufficiently larger than the size of the substrate 28, so that the plurality of substrates 28 can be disposed in the region to which the sputtering particles fly from only one of the longer-side portions 39a and 39b. Therefore, in a case where the target 22 is sufficiently larger than the substrate 28 as in the seventh embodiment, even if one of the longer-side regions 39a and 39b is not covered, there is obtained a thin film c-axis in-plane oriented in the entire substrate with the c-axes thereof being aligned in one direction in the entire substrate. In each of the plurality of substrates 28, a c-axis in-plane oriented ZnO thin film with the c-axes being aligned in a same direction is obtained at one time on the entire surface of each of the substrates, so that the high through-put can be realized.

### Eighth Embodiment

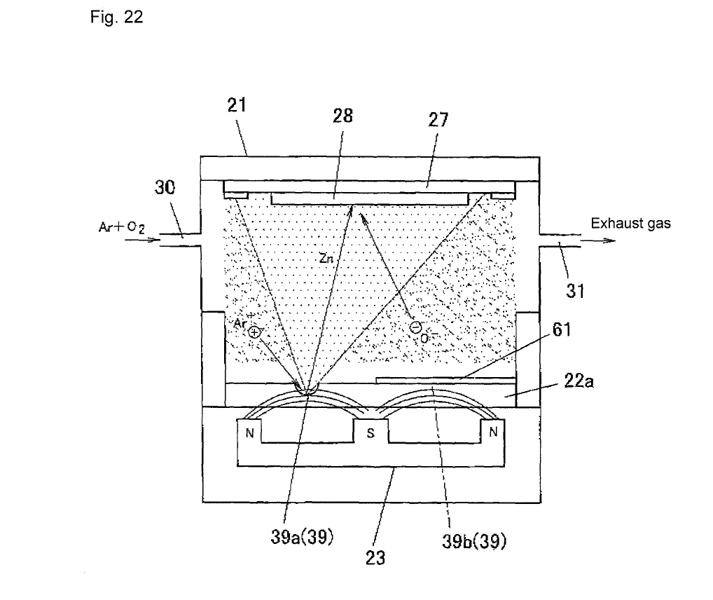

FIG. 22 is a schematic sectional view illustrating a structure of a magnetron sputtering apparatus used to implement a thin film producing method according to an eighth embodiment of the present invention. In the magnetron sputtering apparatus of the eighth embodiment, a Zn target is employed as the target 22a, and a film is deposited on the substrate 28 by the sputtering particles (Zn) emitted from the target 22a and O⁻ in the plasma gas in the vacuum chamber 21.

When the direct-current electric field is applied between the substrate holder 27 and the target 22a, the atmospheric gas (Ar+O₂) in the vacuum chamber 21 is ionized to generate a plasma gas. In the plasma gas, Ar⁺ is attracted to the target 22a to collide with the target 22a, so that Zn is sputtered from the target 22a. The sputtering particles (Zn) emitted from a part of the erosion region 39 (the longer-side portion 39a) of the target 22a are incident on the substrate 28 that is disposed to face the part of the erosion region 39. On the other hand, O⁻ in the plasma gas is attracted to the substrate holder 27 and is incident on the substrate 28.

Zn and O⁻ that are the sputtering particles are incident on the substrate 28 to cause a chemical reaction, thereby forming a ZnO thin film on the surface of the substrate 28.

In the three to eighth embodiments, the film is effectively deposited while the substrate is horizontally and parallelly moved in the direction parallel to the c-axis direction of the ZnO thin film.

The thin film producing method according to the present invention is not limited to ZnO but is effectively applied to deposit a piezoelectric thin film made of aluminum nitride, zinc oxide, gallium nitride, or the like. In these cases, depending on the composition of the thin film, the sputtering particles emitted from at least two types of targets can be crystallized on the substrate to form a thin film.

In the above first to eighth embodiments, the substrate is horizontally disposed. Alternatively, the substrate may be disposed while being inclined in the vacuum chamber. Specifically, the film may be deposited using the substrate disposed such that an angle intersecting the substrate and one linear portion in the region with the high magnetic flux density (the erosion region) is always kept constant.

(Applicable Fields)

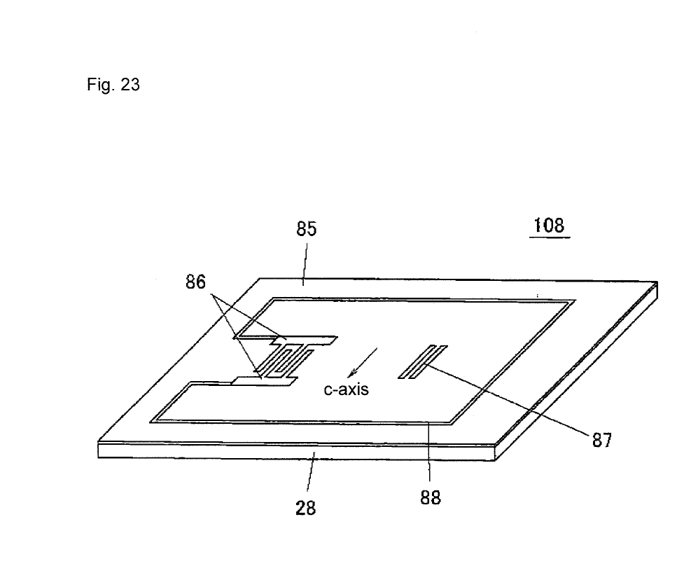

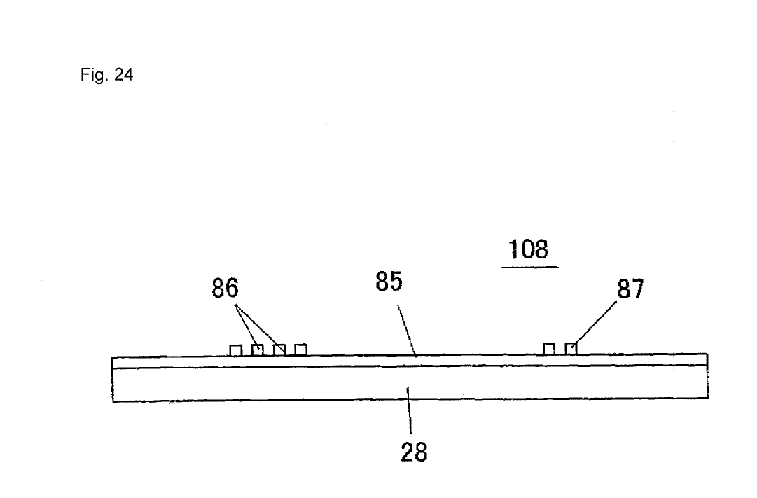

Application examples of the c-axis in-plane oriented ZnO thin film will be described below. FIGS. 23 and 24 each illustrate an SH type SAW (transverse type surface acoustic wave) device 108, wherein FIG. 23 is a perspective view thereof and FIG. 24 is a side view thereof. In the SAW device 108, a ZnO thin film 85 is formed on the surface of the substrate 28, a pair of IDTs (comb electrodes) 86, a reflecting electrode 87, and an antenna 88 are formed of an electrode material on the ZnO thin film 85. The IDTs 86 each include a plurality of electrode fingers that are extended in parallel with each other at a constant pitch. In the pair of IDTs 86, the electrode fingers are disposed so as to mutually engage with each other. The ZnO thin film 85 is c-axis in-plane oriented, and the c-axes thereof are aligned to be parallel to the lengthwise direction of the electrode fingers of IDTs 86.

In the SAW device 108, upon receipt by the antenna 88 of a high-frequency signal in which various frequencies are superimposed, the antenna 88 applies the high-frequency signal between the IDTs 86. Therefore, there is generated a SAW of a transverse type vibrated in the direction parallel to the electrode fingers. The transverse type SAW is canceled unless a wavelength thereof is equal to the gap between the electrode fingers of the IDTs 86. The wavelength of the transverse type SAW depends on the frequency of the high-frequency signal. Accordingly, the SAW device 108 removes the signals that are superimposed in the high-frequency signal and have frequencies other than a predetermined frequency, so that the SAW device 108 functions as a filter to generate a transverse type SAW only including the signals of the predetermined frequency. The transverse type SAW is converted into a high-frequency electric signal using a similar SAW device 108, and the high-frequency electric signal can be transmitted as a radio wave from the antenna 88.

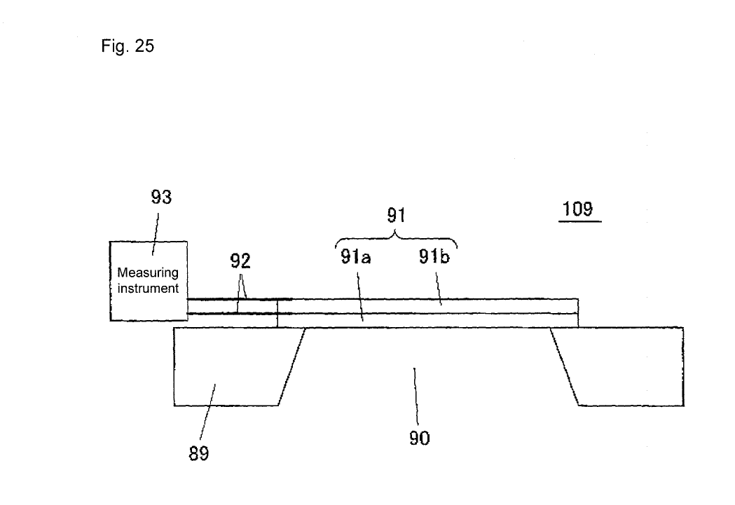

FIG. 25 is a sectional view of a transducer 109. In the transducer 109, a thin-film-like membrane 91 (a diaphragm) is tensioned over an upper surface of a support portion 89 that allows a cavity 90 to path through. In the membrane 91, a ZnO thin film 91b according to the present invention is formed on a substrate 91a such as a metal substrate, a metal-film evaporated substrate obtained by evaporating a metal on a surface thereof. Both upper and lower surfaces of the ZnO thin film 91b are connected to a measuring instrument 93 respectively by lead wires 92.

In a case where the transducer 109 is used as a pressure sensor, a pressure is received by the upper surface thereof to bend the membrane 91, thereby causing a potential difference in the ZnO thin film 91b due to a piezoelectric effect. Therefore, the potential difference is measured with the measuring instrument 93 so as to measure the pressure.

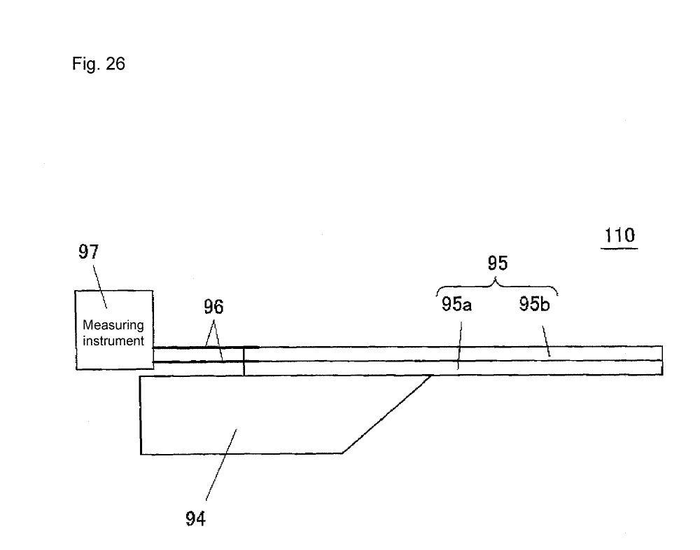

FIG. 26 is a sectional view of another transducer 110. In the transducer 110, a base end portion of a thin-film-like cantilever 95 is fixed to an upper surface of a support portion 94 so as to support the cantilever 95 in a cantilever manner. In the cantilever 95, a ZnO thin film 95b according to the present invention is formed on a substrate 95a such as the metal substrate and the metal-film evaporated substrate obtained by evaporating a metal on the surface thereof. Both upper and lower surfaces of the ZnO thin film 95b are connected to a measuring instrument 97 by lead wires 96.

In a case where the transducer 110 is used as a load sensor, the cantilever 95 is bent when a leading end of the transducer 110 receives a load, and there is caused a potential difference in the ZnO thin film 95b due to the piezoelectric effect. Therefore, the potential difference is measured with the measuring instrument 97 so as to measure the load applied to the leading end of the cantilever 95.

1. A method for producing a thin film on a surface of a substrate by a sputtering method, the thin film producing method comprising:
disposing the substrate so as to face a particle source;
causing an energetic particle emitted from the particle source to be incident on the substrate;
causing the energetic particle to be incident on the surface of the substrate such that a predetermined crystal axis direction is parallel to the surface of the substrate; and
forming a thin film including the energetic particle.

2. The thin film producing method according to claim 1, wherein the thin film is formed by the energetic particle emitted from at least one particle source.

3. The thin film producing method according to claim 1, wherein the thin film is formed by the energetic particle emitted from at least one particle source and a plasma gas particle incident on the substrate.

4. The thin film producing method according to claim 1, wherein the thin film having a hexagonal system is formed on the surface of the substrate.

5. The thin film producing method according to claim 4, wherein c-axis directions of the hexagonal system are parallel to a surface of the thin film, and the c-axes are aligned in one direction.

6. The thin film producing method according to claim 1, wherein the thin film is a piezoelectric thin film.

7. The thin film producing method according to claim 6, wherein the thin film is made of a zinc oxide.

8. The thin film producing method according to claim 1, wherein the particle source is a sputtering target.

9. The thin film producing method according to claim 1, 1 to 3, wherein the particle source is sputtered by discharge in a gas having a pressure of 0.15 Pa or less, so that the particle source emits the energetic particle.

10. The thin film producing method according to claim 1, wherein the substrate is disposed near the particle source.

11. The thin film producing method according to claim 9, wherein the substrate is disposed in a plasma region that is generated by the discharge in the gas.

12. The thin film producing method according to claim 1, wherein an incident angle of the energetic particle to the substrate, an incident direction thereof, or spread of the incident direction thereof is controlled.

13. The thin film producing method according to claim 12, wherein the incident angle of the energetic particle to the substrate, the incident direction thereof, or the spread of the incident direction thereof is controlled by providing a shield plate or a slit in a space between the substrate and the particle source.

14. The thin film producing method according to claim 1, wherein a magnetic circuit is provided behind the particle source, and the thin film is formed on the surface of the substrate only by the energetic particles emitted from the particle source in a linear portion of a region with a high magnetic flux density of a magnetic field generated by the magnetic circuit.

15. The thin film producing method according to claim 1, wherein a magnetic circuit is provided behind the particle source, and the thin film is formed on the surface of the substrate only by the energetic particles emitted from the particle sources in a single linear portion of a region with a high magnetic flux density of a magnetic field generated by the magnetic circuit.

16. The thin film producing method according to claim 15, wherein the magnetic circuit includes an N pole and an S pole to generate the linear region having the high magnetic flux density only between the N pole and the S pole.

17. The thin film producing method according to claim 15, wherein
a partial region of the particle source is covered with a shield plate so as to prevent the energetic particle emitted from the region of the particle source covered with the shield plate from reaching the surface of the substrate, and
the thin film is formed on the surface of the substrate only by the energetic particles emitted from the particle source in the single linear portion of the region with the high magnetic flux density in a region of the particle source not covered with the shield plate.

18. The thin film producing method according to claim 15, wherein
a partial region of the particle source is covered with a hardly-sputtered material so as to prevent the energetic particle emitted from the region of the particle source covered with the hardly-sputtered material from reaching the surface of the substrate, and
the thin film is formed on the surface of the substrate only by the energetic particles emitted from the particle source in the single linear portion of the region with the high magnetic flux density in a region of the particle source not covered with the hardly-sputtered material.

19. The thin film producing method according to claim 15, wherein, in the magnetic circuit, one of an N pole and an S pole is disposed so as to be sandwiched from both sides between the other of the N pole and S pole, and a hardly-sputtered material is used as the particle source in one of regions between the N pole and the S pole.

20. The thin film producing method according to claim 15, wherein, in the magnetic circuit, one of an N pole and an S pole is disposed so as to be sandwiched from both sides between the other of the N pole and S pole, and the particle source is provided only in one of regions between the N pole and S pole.

21. The thin film producing method according to claim 14, wherein the substrate is disposed so as to intersect always at a constant angle with one linear portion in the region with the high magnetic flux density.

22. The thin film producing method according to claim 15, wherein the substrate is disposed so as to intersect always at a constant angle with one linear portion in the region with the high magnetic flux density.

23. A zinc-oxide thin film produced on the surface of the substrate by the thin film producing method according to claim 1 using the particle source made of an zinc oxide, wherein
c-axis directions are parallel to the surface of the substrate and are oriented in one direction in the surface of the substrate.

24. A piezoelectric element, wherein the zinc-oxide thin film according to claim 23 is deposited on a metal substrate or a metal-film evaporation substrate.

25. A transducer including the zinc-oxide thin film according to claim 23.

26. A SAW device including the zinc-oxide thin film according to claim 23.
